(19) United States
(12) Patent Application Publication
(10) Pub. No.: US 2015/0318430 A1
(43) Pub. Date: Nov. 5, 2015

(54) Organic Optoelectronic Component with Infrared Detector

(71) Applicant: OSRAM OLED GmbH, Regensburg (DE)

(72) Inventors: Simon Schicktanz, Regensburg (DE); Erwin Lang, Regensburg (DE)

(21) Appl. No.: 14/650,248

(22) PCT Filed: Dec. 5, 2013
(86) PCT No.: PCT/EP2013/075655

§ 371 Date: Jun. 5, 2015

(30) Foreign Application Priority Data
Dec. 6, 2012 (DE) 10 2012 222 463.7

(51) Int. Cl. H01L 31/14; H01L 51/52; H01L 27/28; H01L 51/44

(52) U.S. Cl. CPC H01L 31/14; H01L 51/44; H01L 51/52; H01L 27/288

(57) ABSTRACT

An organic optoelectronic component includes a substrate, an organic light-emitting element which has an organic light-emitting layer between two electrodes, and an organic radiation-detecting element which has an organic radiation-detecting layer. The organic light-emitting element and the organic radiation-detecting element are arranged on the substrate. The organic light-emitting element is designed to emit visible light during operation and the organic radiation-detecting element is designed to detect infrared radiation during operation.

This patent application is a national phase filing under section 371 of PCT/EP2013/075655, filed Dec. 5, 2013, which claims the priority of German patent application 10 2012 222 463.7, filed Dec. 6, 2012, each of which is incorporated herein by reference in its entirety.

### TECHNICAL FIELD

An organic optoelectronic component is specified.

### BACKGROUND

U.S. Patent Application Publication No. 2007/0194719 A describes an organic optoelectronic component.

### SUMMARY

Embodiments of the invention specify an organic optoelectronic component that is constructed particularly compactly.

In accordance with at least one embodiment of the organic optoelectronic component, the component comprises a substrate. The substrate is the carrying element of the component, on which further component parts of the component are arranged. The substrate is embodied as a rigid body or as a film, which can also be flexible. The substrate comprises two opposite main surfaces connected to one another by side surfaces of the substrate. The substrate can be embodied in a cuboid fashion, for example.

The substrate is formed with a radiation-transmissive material, for example. In this case, it is possible for the substrate to be embodied such that it is pellucid and transparent or milky and translucent to visible light and infrared radiation. In this case, the substrate is embodied such that it is transmissive at least to infrared radiation in the near infrared. Overall, the substrate is then radiation-transmissive at least in the spectral range of near infrared and visible light. Here and hereinafter “radiation-transmissive” or “light-transmissive” means that the radiation-transmissive component part transmits at least 50% of the electromagnetic radiation from the near infrared range and the visible light range that radiates through it. The substrate can, for example, be formed with a plastic or with a glass or consist of one of these materials.

Furthermore, it is possible for the substrate to be embodied such that it is radiation-nontransmissive, for example, reflecting. The substrate can then be formed from a metal or a ceramic material.

Here and hereinafter “radiation-reflecting” or “light-reflecting” means that at least 50% of the radiation from the spectral range of near infrared and/or visible light that impinges on the reflecting element is reflected by the reflecting element.

In accordance with at least one embodiment of the organic optoelectronic component, the component comprises an organic light emitting element. The organic light emitting element forms an organic light emitting diode (OLED), for example. The organic light emitting element comprises at least one organic light emitting layer arranged between two electrodes, for example, an anode and a cathode. In this case, the electrodes of the organic light emitting element can be embodied as radiation-transmissive or radiation-reflecting. In particular, it is possible for both electrodes to be embodied as radiation-transmissive or for one electrode to be embodied as radiation-transmissive and the other electrode to be embodied as radiation-reflecting.

In accordance with at least one embodiment of the organic optoelectronic component, the organic optoelectronic component comprises an organic radiation detecting element. The organic radiation detecting element can be, for example, an organic photodiode or an organic phototransistor. The organic radiation detecting element comprises at least one organic radiation detecting layer, which can be arranged between two electrodes. In this case, it is possible, in particular, for the organic radiation detecting element to be designed for detecting infrared radiation. That is to say that the organic radiation detecting element is not designed for detecting visible light, but rather has a sensitivity in the spectral range at least of the infrared radiation which can penetrate through the substrate. By way of example, the organic radiation detecting element is designed for detecting infrared radiation from the near infrared.

In accordance with at least one embodiment of the organic optoelectronic component, the organic light emitting element and the organic radiation detecting element are arranged on the substrate. In this case, it is possible for the two elements to be arranged alongside one another on the same main surface of the substrate. Furthermore, it is possible for the two elements to be arranged in a manner stacked one above the other on the substrate. Finally, it is also possible for the two elements to be arranged on mutually opposite main surfaces of the substrate.

The two elements can be produced in particular by the same production techniques, for example, by vapor deposition on the substrate.

In accordance with at least one embodiment of the organic optoelectronic component, the component comprises a substrate embodied as radiation-transmissive, an organic light emitting element having an organic light emitting layer between two electrodes, and an organic radiation detecting element having an organic radiation detecting layer.

In this case, both the organic light emitting element and the organic radiation detecting element are arranged on the substrate. In particular, the emission spectrum of the organic light emitting element differs from the absorption spectrum of the organic radiation detecting element. The organic light emitting element is designed to emit visible light during operation, and the organic radiation detecting element is designed to detect infrared radiation during operation.

In this case, the organic optoelectronic component described here is based on the following considerations, inter alia: there are areas of application for optoelectronic components in which it is desired for the optoelectronic components to generate light only if a person is located in proximity to them. The operation of such optoelectronic components requires motion detectors or presence detectors which control the optoelectronic components. In this case, the optoelectronic components and the motion or presence detectors are formed by mutually separate component parts. For reasons of space, in this case often only a small number of motion detectors or presence detectors are arranged in an area, such that often regions of an area in which no person at all is located have to be illuminated.

The organic optoelectronic component described here is now based on the concept of integrating the sensor for a motion detector or a presence detector into the component and of thus specifying a particularly compact optoelectronic component with the aid of which regions of an area in which persons are located can be illuminated in a targeted manner, for example. In this way, the optoelectronic component is particularly compact and helps to save power, since only regions of an area in which persons are actually located are illuminated.

Furthermore, the optoelectronic component can be produced particularly simply since, for producing the radiation detecting element and for producing the light emitting element, it is possible to use the same production methods, such as vapor deposition techniques, for example, for arranging the elements on the substrate. For this purpose, in addition to an organic light emitting diode, that is to say the radiation emitting element, infrared-sensitive organic layers that form the radiation detecting element are applied on the substrate. The radiation detecting element forms a photodiode or a phototransistor which is sensitive in the infrared range. The light emitting element can be controlled depending on signals of the radiation detecting element.

The organic optoelectronic component described here enables a high degree of integration for luminaires and lighting systems with motion or presence detectors. Furthermore, more expedient production is made possible on account of the integration of the radiation detecting element into the component. The organic optoelectronic component described here affords the possibility of realizing illumination, in particular selective illumination, of areas in a cost-effective manner.

In accordance with at least one embodiment of the organic optoelectronic component, the organic light emitting element and the organic radiation detecting are arranged on the same main surface of the substrate in a manner laterally spaced apart from one another. That is to say that the two elements are arranged, for example, adjacent to one another on the same main surface of the substrate, the elements being spaced apart from one another in a lateral direction. In this case, the lateral directions are those directions which run parallel to the main extension directions and the main surfaces of the substrate. The organic light emitting element and the organic radiation detecting element can be arranged, for example, alongside one another on the same main surface of the substrate.

In accordance with at least one embodiment of the organic optoelectronic component, a structured region is formed in the region of the organic radiation detecting element at the main surface of the substrate facing away from the organic radiation detecting element, the structured region acting as a converging lens for the infrared radiation to be detected by the organic radiation detecting element, wherein, on account of the structured region, infrared radiation impinges on the organic radiation detecting element from a larger solid angle range than would be the case without the structured region. In this case, the structured region can be formed in the material of the substrate. That is to say that the material with which the substrate is formed can be structured to form a converging lens, for example, at the main surface facing away from the detecting element.

Furthermore, it is possible for an element that forms the structured region to be arranged at the main surface of the substrate facing away from the detecting element. By way of example, a converging lens can be adhesively bonded onto the main surface of the substrate. At all events the solid angle range from which infrared radiation that is detected by the detecting element is picked up is increased on account of the structured region. In this way, a larger segment of the area in which the organic optoelectronic component is operated can be monitored with regard to infrared radiation sources or changes in the infrared radiation.

In accordance with at least one embodiment of the organic optoelectronic component, the organic light emitting element and the organic radiation detecting element are arranged in a manner stacked one above the other at least in places. That is to say that the two elements are not arranged directly on the same main surface of the substrate, but rather are arranged indirectly on the same main surface of the substrate. By way of example, the light emitting element can be arranged above the radiation detecting element, such that the radiation detecting element is arranged between the light emitting element and the substrate. In this case, it is possible that light generated by the organic light emitting element during operation at least partly passes through the organic radiation detecting element before it leaves the optoelectronic component. That is to say that the radiation detecting element in this case is embodied as radiation-transmissive to the light generated in the light emitting element during operation.

An organic optoelectronic component wherein the light emitting element and the radiation detecting element are arranged in a manner stacked one above the other can be embodied in a particularly space-saving fashion. An electrode arranged between the light emitting element and the radiation detecting element is likewise embodied as radiation-transmissive and can serve for electrically connecting both the light emitting element and the radiation detecting element, which can be connected in series with one another by the electrode.

In accordance with at least one embodiment of the organic optoelectronic component, a light scattering region is formed at the main surface of the substrate facing away from the organic light emitting element and/or at the main surface of the substrate facing the organic light emitting element. The light scattering region can be formed, for example, by a structuring, for example, roughening, of the substrate at at least one of the main surface. Furthermore, it is possible for the light scattering region to be formed by an additional element, such as a scattering layer or a scattering film, for example, which is fixed to the substrate at at least one of the main surface.

In accordance with at least one embodiment of the organic optoelectronic component, the organic light emitting element and the organic radiation detecting element are electrically connected in series with one another, wherein the organic light emitting element is energized upon the reception of infrared radiation by the organic radiation detecting element. If the radiation detecting element is a photodiode, for example, then the latter in the reverse direction is connected in series with the light emitting element. As a result of the reception of infrared radiation, the radiation detecting element is turned on and the light emitting element is thus supplied with operating current. This construction has the advantage that it can be realized particularly simply. One disadvantage may be that weak infrared signals may not suffice to result in energization of the light emitting element.

In accordance with at least one embodiment of the organic optoelectronic component, the organic light emitting element and the organic radiation detecting element are electrically conductively connected to one another by a contact layer formed on the substrate. The contact layer is electrically conductively connected, for example, to a respective electrode of the organic light emitting element and of the organic radiation detecting element. The contact layer can be formed by a metal layer that is vapor-deposited, for example, on the same main surface of the substrate on which the two elements are also arranged.

In accordance with at least one embodiment of the organic optoelectronic component, the component comprises a drive device, which is electrically conductively connected to the organic light emitting element and the organic radiation detecting element, wherein the drive device is designed to control the organic light emitting element depending on signals originating from the organic radiation detecting element. In this case, the drive device can serve, for example, to filter and/or to amplify signals originating from the radiation detecting element, in order to set the sensitivity with which the light emitting element is controlled depending on the signals of the radiation detecting element.

In accordance with at least one embodiment of the organic optoelectronic component, the drive device together with the organic radiation detecting element forms a motion detector or a presence detector. That is to say that, with the aid of the drive device, the organic optoelectronic component becomes an electronic sensor which identifies movements or location of persons in its surroundings in relatively close proximity and operates as an electrical switch for the light emitting element of the component. With the aid of the drive device, it is then possible that the light emitting element can be energized for generating light, for example, as a result of the movement of a person in the area.

In accordance with at least one embodiment of the organic optoelectronic component, the organic light emitting element and the organic radiation detecting element are not directly electrically conductively connected to one another, the drive device is directly electrically conductively connected to the organic radiation detecting element. The drive device is designed to amplify the signals originating from the organic radiation detecting element. The drive device is designed to control a current source, and the current source is directly electrically conductively connected to the organic light emitting element.

In this case, the drive device can be arranged on the substrate or can be arranged in a manner remote from the substrate. Furthermore, it is possible for the drive device to be part of a driver for the organic optoelectronic component, which, alongside the drive device, also comprises the current source for operating the light emitting element. By virtue of the fact that the organic light emitting element and the organic radiation detecting element are not directly electrically conductively connected to one another, the signals of the radiation detecting element can be amplified by the drive device, without directly influencing the operation of the light emitting element. The light emitting element is then switched depending on the signals via the current source, which is likewise connected to the drive device.

Furthermore, a luminaire is specified, comprising at least one organic optoelectronic component according to any of the preceding claims. That is to say that all features disclosed for the organic optoelectronic component are also disclosed for the luminaire. In this case, the at least one optoelectronic component forms a light source of the luminaire. In particular, it is possible for two or more of the optoelectronic components described here to be arranged in a common luminaire housing of the luminaire. The luminaire can be used, for example, for general lighting, for lighting corridors or for exterior lighting, wherein the radiation detecting element of the components together with a drive device can form a motion detector or a presence detector.

### BRIEF DESCRIPTION OF THE DRAWINGS

The organic optoelectronic component described here is explained in greater detail below on the basis of exemplary embodiments and the associated figures.

FIGS. 1A, 1B, 2A, 2B show, on the basis of schematic illustrations, exemplary embodiments of organic optoelectronic components described here.

With reference to FIGS. 3A, 3B and 3C, exemplary embodiments of organic optoelectronic components described here are explained in greater detail.

With reference to the schematic illustrations in FIGS. 4A, 4B, 4C, the use of luminaires described here is explained in greater detail.

Elements that are identical, of identical type or act identically are provided with the same reference signs in the figures. The figures and the size relationships of the elements illustrated in the figures among one another should not be regarded as to scale. Rather, individual elements may be illustrated with exaggerated size in order to enable better illustration and/or in order to afford a better understanding.

### DETAILED DESCRIPTION OF ILLUSTRATIVE EMBODIMENTS

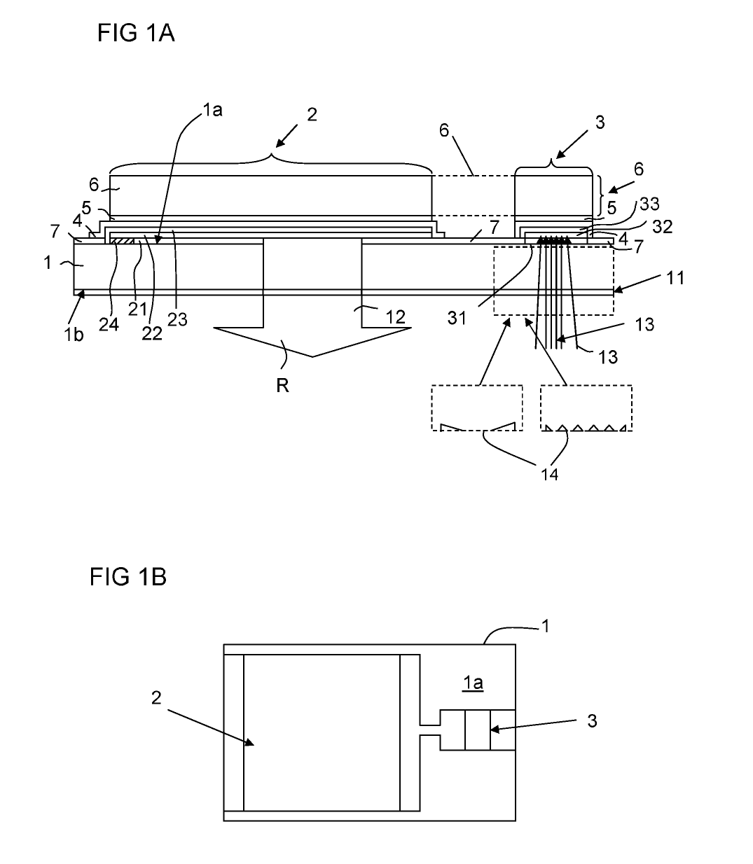

The schematic sectional illustration in FIG. 1A shows a first exemplary embodiment of an organic optoelectronic component described here. In the case of the exemplary embodiment in FIG. 1A, an organic light emitting element 2 and an organic radiation detecting element 3 are arranged on a first main surface 1a of a substrate 1 in a manner laterally spaced apart from one another. The substrate 1 is formed with a material that is transmissive to light and infrared radiation. By way of example, the substrate 1 consists of glass. The light emitting element 2 and the radiation detecting element 3 are applied in a coplanar manner on the first main surface la of the substrate, for example, by a vapor deposition process.

The light emitting element 2 comprises a first electrode 21, which is a transparent anode, for example, at least one light generating organic layer 22 and a second electrode 23, which is a cathode, for example, which can be embodied as radiation-reflecting or radiation-transmissive.

The radiation detecting element 3 likewise comprises a first electrode 31, at least one organic radiation receiving layer 32 and a second electrode 33.

Both elements 2, 3 are encapsulated with a thin-film encapsulation, which can be produced, for example, by a PE-CVD method (plasma-enhanced chemical vapor deposition) and/or an ALD method (atomic layer deposition) such as, for example, flash-ALD, photoinduced ALD and/or physical vapor deposition. In this case, it is possible for the encapsulation layer sequence 4 to enclose both elements 2, 3 and for both elements to be encapsulated with the encapsulation layer sequence 4 in a single production method.

Optionally, a covering body 6 can be arranged at that side of the two elements 2, 3 which faces away from the substrate 1, the covering body being fixed to the encapsulation layer sequence 4 by a connecting means 5. By way of example, the connecting means 5 is a lamination adhesive and the covering body 6 is a laminated film, a glass or some other covering element. In this case, it is possible for the covering body 6 to extend as a single covering body of the component over both elements.

During the operation of the optoelectronic component, the light emitting element 2 generates light 12 that is emitted in a main emission direction R. In this case, the emission of light takes place through the substrate 1. In this case, a light scattering region 11, for example, in the form of a scattering film, a scattering layer, a roughening of the substrate at the surface and/or in the form of scattering centers in the substrate, can optionally be formed at the second main surface 1b facing away from the first main surface 1a. Furthermore, it is optionally, alternatively or additionally possible for another light scattering region (not illustrated) to be formed at the first main surface la of the substrate in the same way.

Infrared radiation 13 from outside the component penetrates through the substrate 1 to the radiation detecting element 3 and is converted into signals there. These electrical signals can be forwarded ,for example, via the contact layer 7, which can be embodied as contact metallization at the first main surface 1a. In this case, an insulating layer 24 can be arranged, for example, between the contact layer 7 and one of the electrodes.

As shown in FIG. 1A, the second main surface 1b facing away from the first main surface la can comprise a structured region 14, in which the substrate is embodied as a converging lens for infrared radiation 13 or where an optical element that acts as a converging lens for infrared radiation is fixed to the substrate 1. The structured region 14 in this case ensures that infrared radiation impinges on the radiation detecting element 3 from a larger solid angle range than would be the case without the structured region 14.

FIG. 1B shows a schematic plan view of the first main surface 1a. As can be gathered from FIG. 1B, the two elements 2a, 2b can be electrically connected in series with one another, for example, by the contact layer 7.

Possible circuit diagrams in this respect are shown in FIGS. 3A and 3B. FIG. 3A relates to an exemplary embodiment wherein the radiation detecting element 3 is embodied as an infrared photodiode. The light emitting element 2 is connected in series with the radiation detecting element 3, wherein the radiation detecting element 3 is connected in the reverse direction. Upon reception of infrared radiation 13, the detecting element 3 is turned on and the light emitting element 2 can be energized for generating radiation.

In FIG. 3B, in contrast to the exemplary embodiment in FIG. 3A, the radiation detecting element 3 is not formed by a photodiode, but rather by an infrared phototransistor.

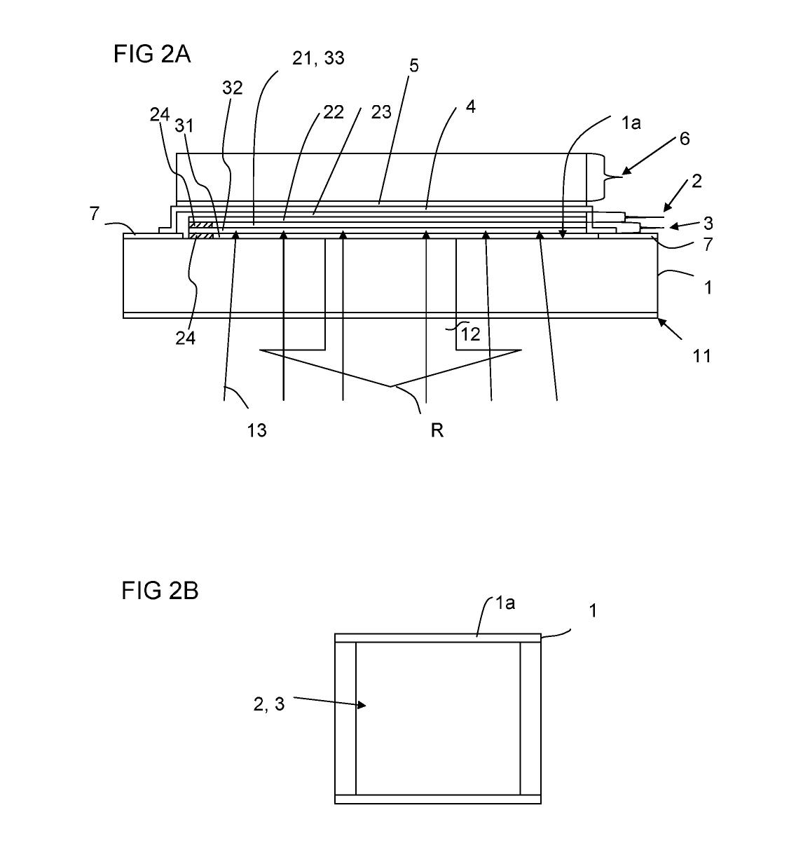

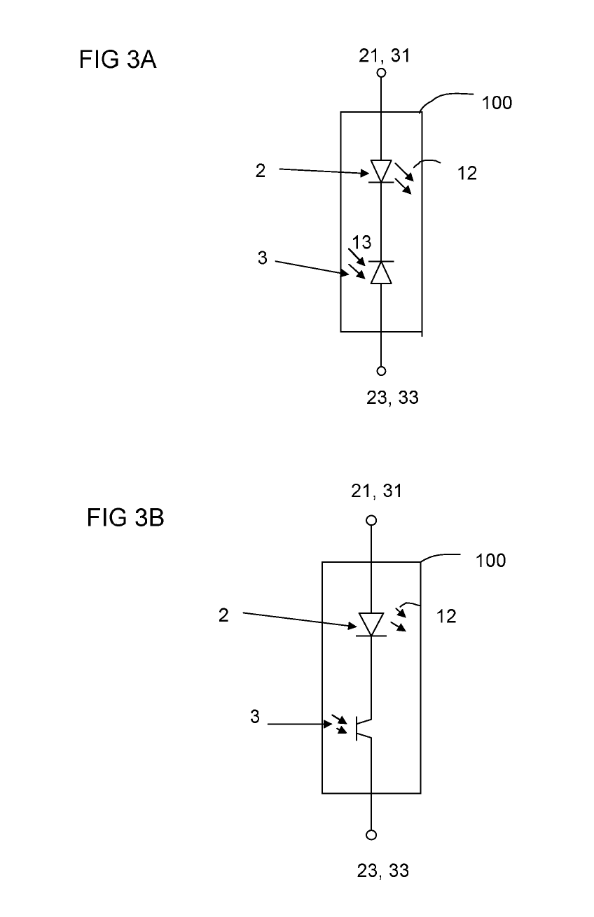

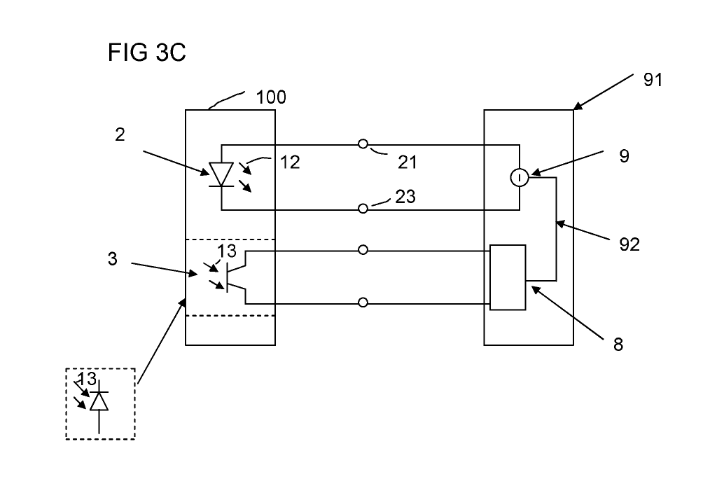

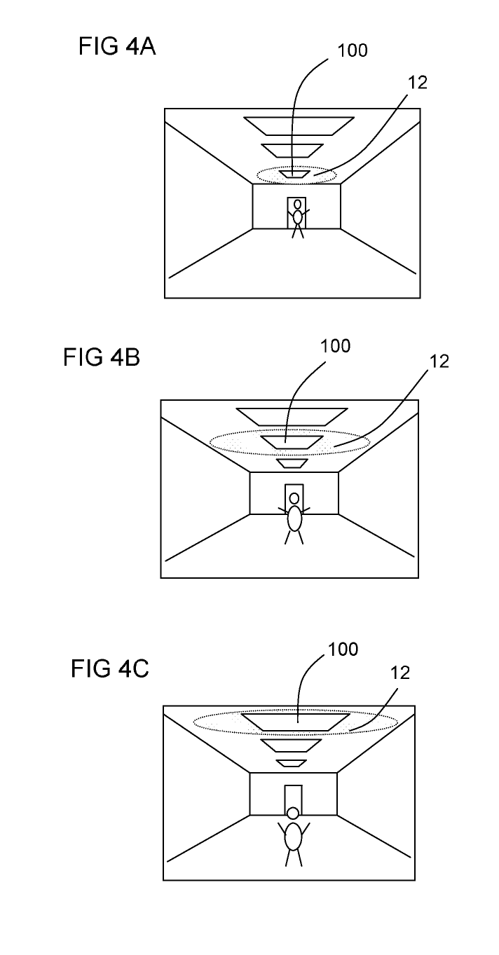

In conjunction with FIGS. 2A, 2B an exemplary embodiment is described wherein the radiation detecting element 3 and the light emitting element 2 are arranged in a manner stacked one above the other, wherein the radiation detecting element 3 directly adjoins the substrate 1 and the light emitting element 2 and is arranged between these two component parts.

The two elements 2, 3 share the electrode 21, 33 embodied as transmissive to the light 12 generated in the light emitting element 2. The radiation detecting element 3 is also embodied as transmissive to the light 12. The exemplary embodiment in FIG. 2A has the advantage that the infrared radiation 13 can be detected over the entire emission surface of the optoelectronic component. In this way, infrared radiation can be picked up from a particularly large solid angle range.

A schematic plan view of the first main surface 1a of the substrate 1 of the component in FIG. 2A is shown in conjunction with FIG. 2B.

A further basic schematic circuit diagram concerning the interconnection of the elements 2, 3 of the component is shown in conjunction with FIG. 3C. In this case, the radiation detecting element 2 is directly electrically conductively connected to a drive device 8 comprising an amplifier, for example, which conditions the signals of the detecting element 2 and passes them via the control line 92 to a current source 9. Current source 9 and drive device 8 can be part of a driver 91.

In the case of the exemplary embodiment in FIG. 3C, the light emitting element 2 and the radiation detecting element 3 are not directly electrically conductively connected to one another. The radiation detecting element 3 can be embodied as an infrared phototransistor or as an infrared photodiode. The light emitting element 2 and the radiation detecting element 3 are in particular not electrically conductively connected to one another by lines formed on the substrate 1.

In the exemplary embodiment in FIG. 3C, the component 100 can comprise the driver 91, that is to say that the component parts of the driver 91 can be arranged on the substrate 1 and can, for example, likewise be formed with organic component parts. In this case, it is possible for all component parts, that is to say the elements 2, 3, the current source 9 and the drive device 8, to be jointly encapsulated.

However, it is also possible for the driver 91 to be arranged separately from the component 100 and not to be part of the component 100.

The use of a luminaire described here, which comprises at least one component 100 described here as light source, is described in greater detail in conjunction with FIGS. 4A to 4C. In the case of this luminaire, the radiation detecting element 3 of the component 100 together with a drive device forms a motion detector which detects the motion of a person in an area and correspondingly activates the light emitting element 2 of the optoelectronic component.

In this way, a light can be tracked, for example, to a person moving in an area or a corridor. In this case, it is possible for the brightness of the light from an already active lamp to be increased for a specific time or for the lamp to be switched on for specific times. Energy-efficient illumination is thus achieved, since illumination is effected only at locations at which lighting is required. On account of the integration of the radiation detecting element 3 into the same component as the light emitting element 2, a particularly compact luminaire is achieved.

The invention is not restricted to the exemplary embodiments by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

1-14. (canceled)

15. An organic optoelectronic component comprising:
a substrate;
an organic light emitting element having an organic light emitting layer between two electrodes; and
an organic radiation detecting element having an organic radiation detecting layer;
wherein the organic light emitting element and the organic radiation detecting element are arranged on the substrate;
wherein the organic light emitting element is designed to emit visible light during operation; and
wherein the organic radiation detecting element is designed to detect infrared radiation during operation.

16. The organic optoelectronic component according to claim 15, wherein the organic light emitting element and the organic radiation detecting element are arranged on the same main surface of the substrate in a manner laterally spaced apart from one another.

17. The organic optoelectronic component according to claim 15, wherein a structured region is formed in a region of the organic radiation detecting element at a main surface of the substrate facing away from the organic radiation detecting element, the structured region acting as a converging lens for infrared radiation.

18. The organic optoelectronic component according to claim 17, wherein, on account of the structured region, infrared radiation impinges on the organic radiation detecting element from a larger solid angle range than would be the case without the structured region.

19. The organic optoelectronic component according to claim 15, wherein the organic light emitting element and the organic radiation detecting element are stacked one above the other at least in places.

20. The organic optoelectronic component according to claim 19, wherein light generated by the organic light emitting element during operation at least partly passes through the organic radiation detecting element before it leaves the organic optoelectronic component.

21. The organic optoelectronic component according to claim 15, wherein a light scattering region is formed at a main surface of the substrate facing away from the organic light emitting element.

22. The organic optoelectronic component according to claim 15, wherein the organic light emitting element and the organic radiation detecting element are electrically connected in series with one another, and wherein the organic light emitting element is energized upon reception of infrared radiation by the organic radiation detecting element.

23. The organic optoelectronic component according to claim 22, wherein the organic light emitting element and the organic radiation detecting element are electrically conductively connected to one another by a contact layer disposed on the substrate.

24. The organic optoelectronic component according to claim 15, further comprising a drive device, electrically conductively connected to the organic light emitting element and the organic radiation detecting element, wherein the drive device is configured to control the organic light emitting element depending on signals originating from the organic radiation detecting element.

25. The organic optoelectronic component according to claim 24, wherein the drive device together with the organic radiation detecting element forms a motion detector or a presence detector.

26. The organic optoelectronic component according to claim 24, wherein:
the organic light emitting element and the organic radiation detecting element are not directly electrically conductively connected to one another;
the drive device is directly electrically conductively connected to the organic radiation detecting element;
the drive device is configured to amplify the signals originating from the organic radiation detecting element;
the drive device is configured to control a current source; and
the current source is directly electrically conductively connected to the organic light emitting element.

27. The organic optoelectronic component according to claim 15, wherein the emission spectrum of the organic light emitting element differs from the absorption spectrum of the organic radiation detecting element.

28. The organic optoelectronic component according to claim 15, wherein the organic optoelectronic component is a light source for illuminating areas.

29. A luminaire comprising an organic optoelectronic component according to claim 15, wherein the optoelectronic component forms a light source of the luminaire.

30. An organic optoelectronic component comprising:
a substrate;
an organic light emitting element having an organic light emitting layer between two electrodes; and
an organic radiation detecting element having an organic radiation detecting layer;
wherein the organic light emitting element and the organic radiation detecting element are arranged on the substrate;
wherein the organic light emitting element is designed to emit visible light during operation;
wherein the organic radiation detecting element is designed to detect infrared radiation during operation; and
wherein the organic optoelectronic component is a light source for illuminating areas.

31. An organic optoelectronic component comprising:
a substrate;
an organic light emitting element having an organic light emitting layer between two electrodes;
an organic radiation detecting element having an organic radiation detecting layer; and
a drive device, which is electrically conductively connected to the organic light emitting element and the organic radiation detecting element;
wherein the organic light emitting element and the organic radiation detecting element are arranged on the substrate;
wherein the organic light emitting element is designed to emit visible light during operation;
wherein the organic radiation detecting element is designed to detect infrared radiation during operation; and
wherein the drive device is designed to control the organic light emitting element depending on signals originating from the organic radiation detecting element.
